(19) United States
(12) Patent Application Publication
(10) Pub. No.: US 2026/0005128 A1
(43) Pub. Date: Jan. 1, 2026

(54) MODULARIZED CONSTRUCT FOR COMPLEX CHIPLET INTEGRATION PACKAGE

(71) Applicant: Advanced Micro Devices, Inc., Santa Clara, CA (US)

(72) Inventor: Kong Toon NG, Hsinchu (TW)

(21) Appl. No.: 18/761,027

(22) Filed: Jul. 1, 2024

(51) Int. Cl. H01L 23/52; H01L 23/00; H01L 23/31; H01L 25/00; H01L 25/10

(52) U.S. Cl. CPC H01L 23/52; H01L 23/3107; H01L 23/562; H01L 24/97; H01L 25/105; H01L 25/50; H01L 24/16; H01L 2224/16245; H01L 2224/95001

(57) ABSTRACT

Modularized construction of a structure is used for a multi-die integration package. Segregation of complex devices into substructures (sub-modules) are tested and verified as functional before final reconstitution into the multi-die integration package. The thermal coefficient of sub-modules can be fine-tuned for low chip module warpage. The sub-modules can be made with a glass interposer tuned with a certain coefficient of thermal expansion (CTE) and modulus to provide favorable warpage performance. Solder interconnects at high stress locations may be used to further reduce via and polyimide (PI) stresses. A minimal redistributed layer (RDL) comprising conductive metal patterns with a plurality of metal contacts thereon is formed on a polyimide (PI) or glass carrier and electrically interconnects the sub-modules together.

### TECHNICAL FIELD

Embodiments of the present disclosure generally relate to packaging of multi-die integration packages, and in particular, to modularized construction of a multi-die structure using an elevated fan-out bridge and at least one semiconductor integrated circuit (IC) die and/or chiplet in the multi-die integration package.

### BACKGROUND

Multi-die integration packages utilizing integrated circuit (IC) die and/or chiplet modules can grow to a significant size. As the multi-die integration packages comprising the IC die and/or chiplet modules grow in size, the risk for failure of an integrated circuit chip die bond to a die stack substrate increases significantly. This is especially true for machine learning applications where the next generation products could very well exceed 5,000 mm² of the module area. This creates huge concerns on manufacturing yield as the gross die per reconstituted wafer may be significantly reduced to single digit numbers. This will inevitably have repercussions to yield, capacity and product cost.

### SUMMARY

In one example of the disclosure, a multi-die integration package includes: An elevated fan-out bridge structure comprising: A minimal redistributed layer (RDL) including conductive metal patterns with a plurality of metal contacts thereon. At least one bridge die attached and electrically coupled to the plurality of metal contacts of the conductive metal patterns of the RDL. At least one sub-module attached and electrically coupled to the plurality of metal contacts of the conductive metal patterns of the RDL. At least one integrated circuit (IC) die attached and electrically coupled to the plurality of metal contacts of the conductive metal patterns of the RDL.

In one example of the disclosure, a method for fabricating a multi-die structure includes: Creating a redistributed layer (RDL) on a first carrier, the RDL comprising conductive metal patterns with a plurality of contacts thereon. Attaching and electrically coupling at least one bridge die to the contacts of the conductive metal patterns of the RDL. Attaching and electrically coupling at least one sub-module to the contacts of the conductive metal patterns of the RDL. Encasing the at least one bridge die and the at least one sub-module with first mold material. Removing the first carrier from the RDL and the first mold material encasing the at least one bridge die and the at least one sub-module. Attaching a second carrier to an opposite side of the at least one bridge die and the at least one sub-module. Attaching and electrically coupling the at least one chiplet to the contacts of the conductive metal patterns of the RDL on an opposite side thereof. Encasing the at least one chiplet and the opposite side of the RDL with a second mold material. Removing the second carrier from the at least one chiplet. Back grinding the at least one bridge die and the at least one sub-module to expose electrical circuit connections thereof. Patterning and attaching contacts to the exposed electrical circuit connections.

In one example of the disclosure, an elevated fan-out bridge structure, includes: A minimal redistributed layer (RDL) including conductive metal patterns with a plurality of metal contacts thereon. At least one bridge die attached and electrically coupled to the plurality of metal contacts of the conductive metal patterns of the RDL. At least one sub-module attached and electrically coupled to the plurality of metal contacts of the conductive metal patterns of the RDL.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates schematic elevational layout views of a prior art multi-die structure.

FIG. 2 illustrates representative schematic elevational layout views of a multi-die structure, according to an example.

FIG. 3 illustrates a schematic elevational layout view of a prior art multi-die or wafer level fan out structure.

FIG. 4 illustrates representative schematic elevational layout views of a multi-die structure having a sub-module with a solder interconnect for stress relief at a high stress interconnection location, according to an example.

FIG. 4A illustrates a representative schematic plan view of a redistributed layer (RDL) substrate comprising a plurality of multi-die structures, according to an example.

FIGS. 5A, 5B and 5C illustrate representative schematic elevational layout views and process flow steps for fabricating a multi-die structure, according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Modularized construction of a multi-die structure may use an elevated fan-out bridge in combination with at least one IC die and/or chiplet for creating a multi-die integration package for use as a system-on-chip (SoC) device. Segregation of complex devices into substructures (sub-modules) may be tested and verified as functional before final reconstitution into the multi-die integration package. Higher yields may be obtained by segregating the entire structure into smaller substructures (sub-modules) that are pre-fabricated in a manufacturing sub-flow, tested and later reconstituted into the final structure. Manufacture of the smaller pre-fabricated sub-modules are expected to be high yielding. Thus, very complex and/or large form factor multi-die integration packages may be built without significant impact to process yield over the yields of the individual sub-modules.

As the multi-die integration package grows in size, the risk for chip-on-substrate die bond failure increases significantly. According to the teachings of this disclosure, this risk may be mitigated by using suitable materials in the smaller sub-modules. This allows a new degree of freedom to mitigate chip module warpage risk as the thermal coefficient of sub-modules may be fine-tuned to enable low chip module warpage overall. For example, instead of standard mold encased sub-modules, the sub-modules may be made with a glass interposer tuned with a certain coefficient of thermal expansion (CTE) and modulus to provide favorable warpage performance. Solder interconnects at high stress locations may be used to further reduce via and polyimide (PI) stresses. The connection of a via cap, normally attached directly to the silicon, may be modified with the addition of a solder interconnection at a high stress connection location thereof.

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. Referring now to the drawing figures, the details of examples are representative layouts schematically illustrated. Like elements in the drawing figures will be represented by like numbers, and similar elements will be represented by like numbers with a different lower-case letter suffix.

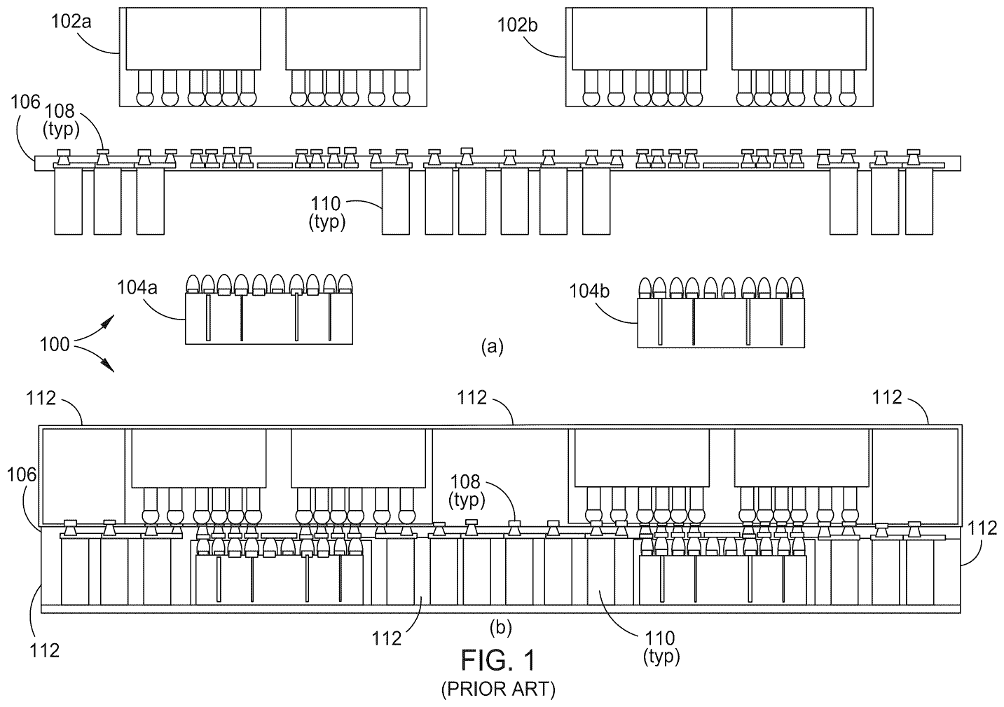

Referring to FIG. 1, depicted are schematic elevational layout views of a prior art multi-die structure. A prior art multi-die structure is generally represented by the numeral 100. An exploded view thereof is shown in drawing (a) and a reconstitution view thereof is shown in drawing (b). The multi-die structure 100 comprises at least one IC die 102, at least one bridge die 104 and a complex redistributed layer (RDL) 106 created on a carrier or glass panel. The complex RDL 106 includes via caps 108 and conductors 110. The at least one bridge die 104, redistributed layer (RDL) 106, via caps 108 and conductors 110 are adapted to create a fan-out bridge structure. The at least one IC die 102, the at least one bridge die 104, the redistributed layer (RDL) 106, the via caps 108 and the conductors 110 are electrically coupled together and then encapsulated with encapsulation material 112. However, high via and PI stresses must be controlled through design rules. For example, stack vias are not allowed and mesh is required above the via caps 108 to reduce stress thereon.

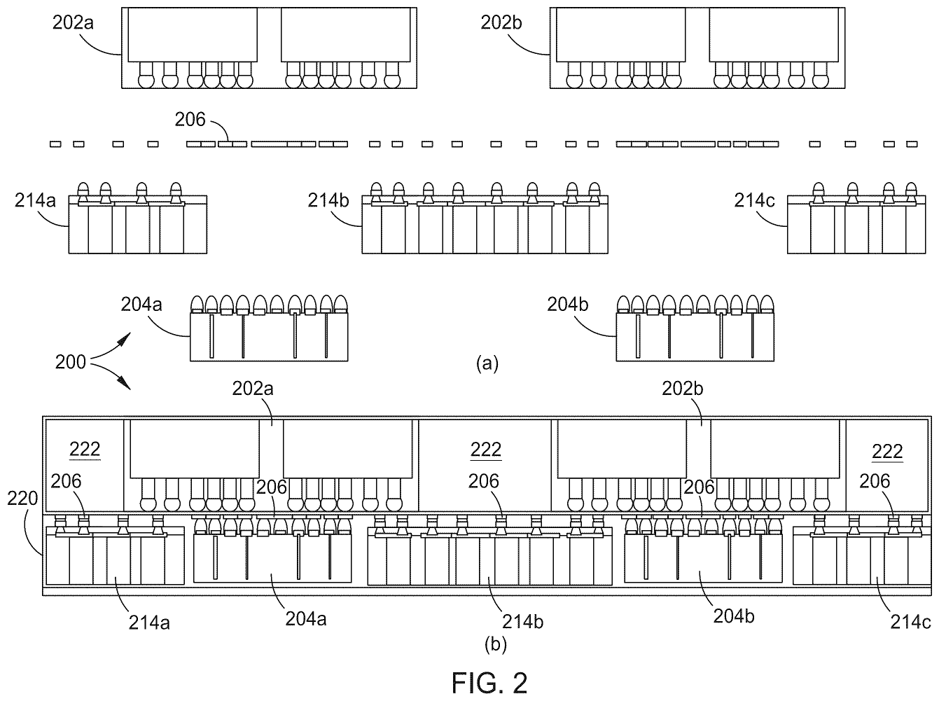

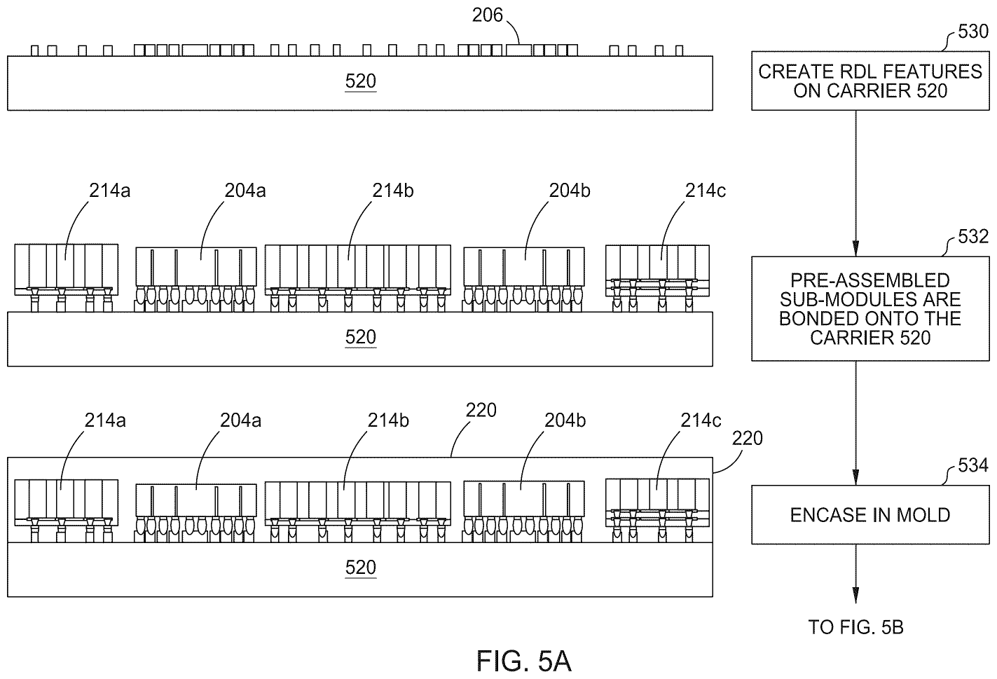

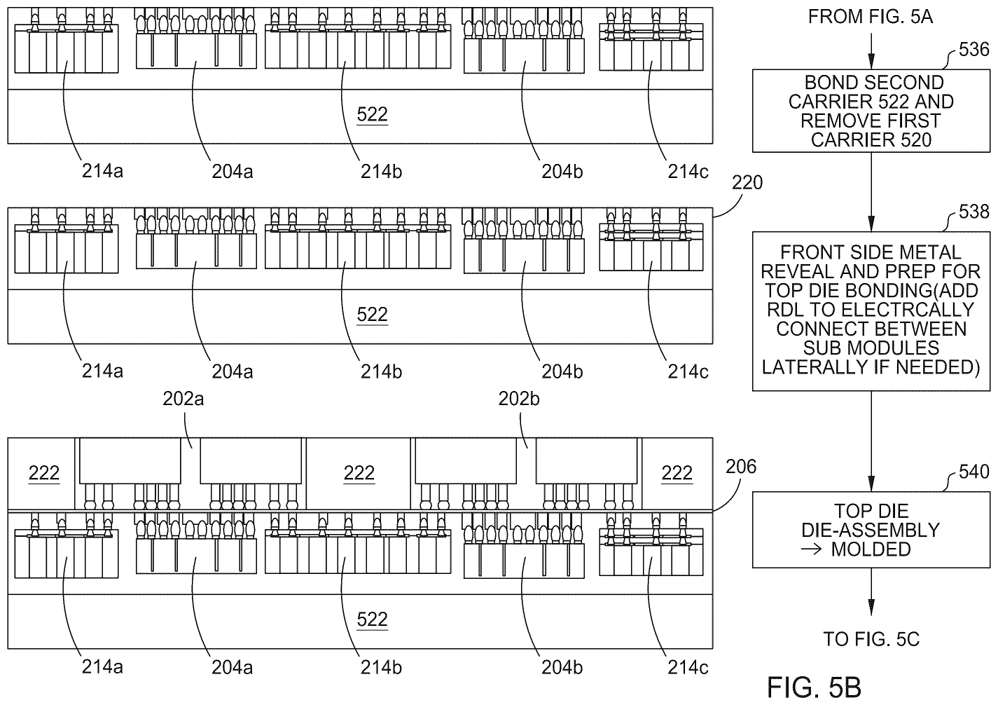

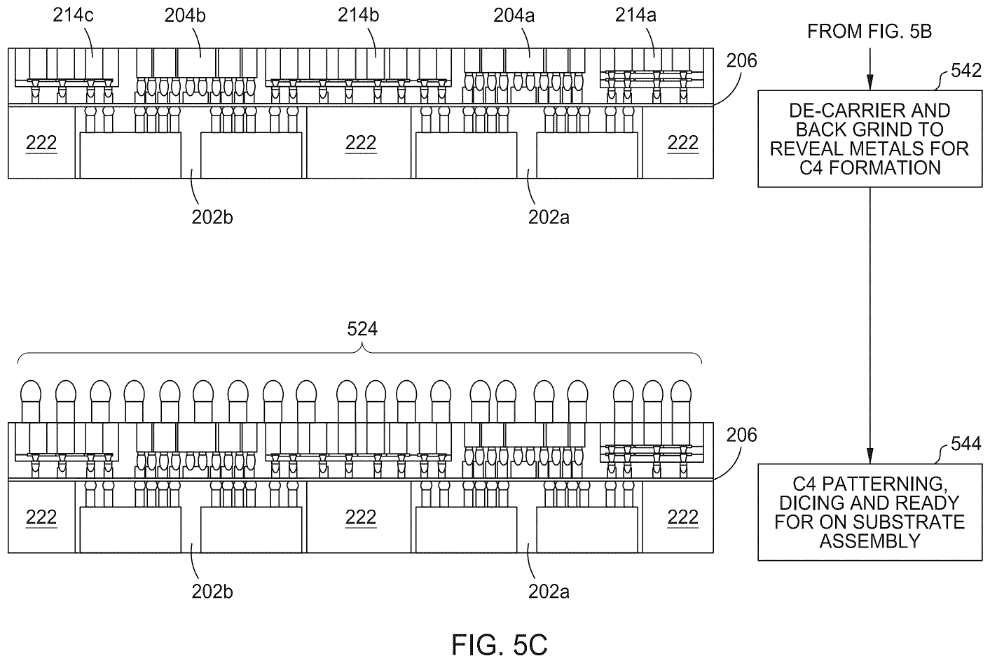

Referring to FIG. 2, depicted are schematic elevational layout views of a multi-die structure, according to an example. A multi-die structure, according to the teachings of this disclosure, is generally represented by the numeral 200. An exploded view thereof is shown in drawing (a) and a reconstitution view thereof is shown in drawing (b). The multi-die structure 200 comprises at least one IC die and/or chiplet 202, at least one bridge die 204, at least one sub-module 214 and a minimal redistributed layer (RDL) 206 created on a carrier (FIG. 5). The minimal RDL 206 comprises conductive metal patterns with a plurality of metal contacts thereon (a simple metal interposer), whereas the complex RDL 106 includes via caps 108 and conductors 110 created on a carrier or glass panel. The at least one IC die and/or chiplet 202, the at least one bridge die 204 and the at least one sub-module 214 are electrically coupled to the plurality of metal contacts on the minimal RDL 206, and then encapsulated with encapsulation materials 220 and 222 to form the multi-die structure 200.

The at least one IC die and/or chiplet 202, the at least one bridge die 204, and/or the at least one sub-module 214 may be pre-fabricated and tested before being reconstituted into the multi-die structure 200. Knowing that only modules that are operating properly will be reconstituted into the multi-die structure 200, greatly improves the total package yield. Also, the conductive metal patterns of the minimal RDL 206 may be configured for different submodule connection pitches so that a variety of different modules may be integrated together with only having to customize the RDL 206 for the desired module integration into the multi-die structure 200. No via structures (item 110 of FIG. 1), via end caps 108, and a complex sandwiched structure interpose 106 are required. Rather just a very simple patterned conductive layer created on a carrier 520 (FIG. 5A) need be provided. The patterned conductive layer may be designed for any contact pitch configurations of the sub-modules. Thus, giving greater flexibility and availability of sub-modules that may be used to build the multi-die structure 200.

It is contemplated and with the scope of this disclosure that a complex integrated circuit die may be used with or in place of a chiplet. A purpose and advantage of the teachings of this disclosure is to more advantageously use chiplets to build systems-on-chip (SoC) devices. Chiplets are designed to be used in a chiplet-based architecture, in which multiple chiplets may be coupled together to form a complete system-on-chip (SoC).

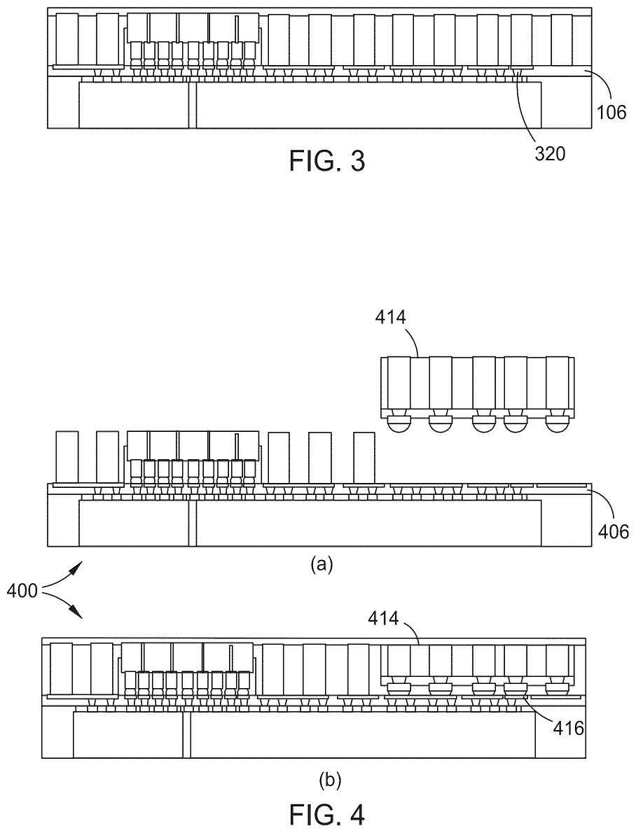

Referring to FIG. 3, depicted is a schematic elevational layout view of a prior art multi-die or wafer level fan-out structure. The RDL 106 comprises copper-to-copper contacts, whereby there may be high via/polyimide (PI) stresses at bond pad vias (BPVs) 320 located at die corners, especially on large form factor multi-die structures. These stresses may lead to electrical failures in the multi-die structure, thereby reducing product yields.

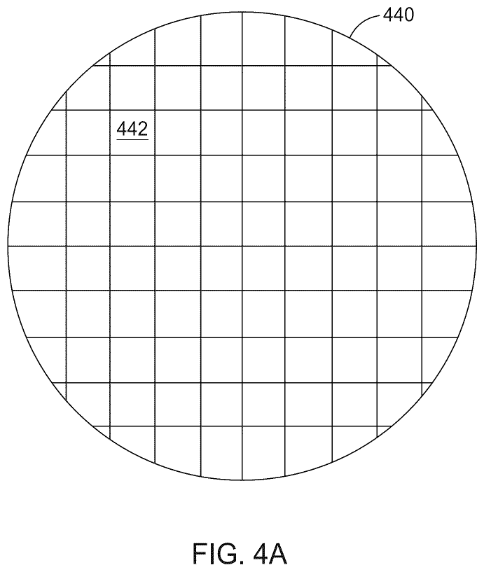

Referring to FIG. 4, depicted are representative schematic elevational layout views of a multi-die structure having a sub-module with a solder interconnect for stress relief at a high stress interconnection location, according to an example. A multi-die structure, according to the teachings of this disclosure, is generally represented by the numeral 400. A partial exploded view thereof is shown in drawing (a) and a reconstitution view thereof is shown in drawing (b). The multi-die structure 400 comprises the aforementioned IC die and/or chiplets, bridge die(s), and at least one sub-module 414 having a solder interconnection(s) 416 at a high stress location(s) on the metal patterned redistributed layer (RDL) 406. Via and polyimide (PI) interconnection stresses between a module, e.g., sub-module 414 to RDL 406 may be mitigated in, for example but not limited to, a die first application by providing a solder interconnection at a high stress location 416, typically but not limited to, die corners on the via cap directly connected to the silicon.

Referring to FIG. 4A, depicted is a representative schematic plan view of a redistributed layer (RDL) interposer comprising a plurality of multi-die structures, according to an example. A plurality of multi-die structures 200 may be fabricated on a wafer sized substrate 440 (see FIG. 5). Then separated into individual multi-die structures 200 after fabrication of the aforementioned modules thereon. The separated multi-die structures 200 are now ready for packaging into integrated circuit packages that are adapted for attachment and electrically coupled to an electronics system substrate (e.g., printed circuit board).

Referring to FIGS. 5A, 5B and 5C, depicted are schematic elevational layout views and process flow steps for fabricating a multi-die structure, according to an example. In step 530 a minimal redistributed layer (RDL) 206 is created on a first carrier 520. The RDL 206 comprises conductive metal patterns with a plurality of metal contacts thereon. In step 532 the bridge dies 204 and sub-modules 214 are attached and electrically coupled to the RDL 206 being supported by the first carrier 520. The bridge dies 204 and sub-modules 214 may be pretested for proper operation to improve finished multi-die structure 200 yields.

In step 534 the bridge dies 204 and sub-modules 214 attached and electrically coupled to the RDL 206 may be encased in mold material 220. In step 536 (FIG. 5B) a second carrier 522 is added to the opposite faces of the bridge dies 204 and sub-modules 214. Then the first carrier 520 may be removed. In step 538 the front side metal connections are revealed (RDL 206), after removal of the first carrier 520 in step 536, and prepared for bonding to the IC die and/or chiplets 202 in step 540. In step 540 the IC die and/or chiplets 202 and RDL 206 are electrically connected together to produce a top die assembly (chiplets 202 and RDL 206) and encased in mold material 222.

In step 542 (FIG. 5C) the second carrier 522 is removed and the mold material 222 is back ground to reveal the metal of the at least one bridge die 204 and the at least one sub-module 214 to facilitate formation of C4 connections 524. In step 544 the C4 connections 524 are patterned, the plurality of multi-die structures 200 are separated (diced) and then are ready for assembly onto substrates (not shown).

For the examples disclosed above, connections between the vias (TSVs) of the active dice, interposer(s), substrate and passive pass-through dice may be done with lower resistance metal bonding pads, e.g., hybrid-bonding, copper hybrid-bonding instead of using micro bumps in the power delivery paths and may significantly lower resistance of the electrical connections. This solves a significant voltage drop problem associated with using micro bumps for electrical power circuit connections. An added benefit is elimination of the layer-to-layer (D2D) layers between the silicon wafers, allowing direct metal-to-metal electrical connections (hybrid-bonding) between layer layers, thereby further reducing the resistance of connections there between. In addition, the layer stack thickness will be reduced and heat transfer improved there-through.

In the examples disclosed hereinabove, the various semiconductor dice are illustrated or otherwise presumed to be “face down” (e.g., back end of line-BEOL metal layers facing toward the bottom of the stack, bulk silicon/backside facing upward toward the top of the stack). However, different examples may utilize one or more IC die and/or chiplets or other silicon components in “face up” orientations as well.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. A multi-die integration package, comprising:
an elevated fan-out bridge structure, comprising:
a minimal redistributed layer (RDL) including conductive metal patterns with a plurality of metal contacts thereon,
at least one bridge die attached and electrically coupled to the plurality of metal contacts of the conductive metal patterns of the RDL, and
at least one sub-module attached and electrically coupled to the plurality of metal contacts of the conductive metal patterns of the RDL; and
at least one integrated circuit (IC) die attached and electrically coupled to the plurality of metal contacts of the conductive metal patterns of the RDL.

2. The multi-die integration package according to claim 1, wherein the conductive metal patterns of the RDL are formed on a polyimide (PI) or glass carrier.

3. The multi-die integration package according to claim 1, wherein the at least one IC die is at least one chiplet.

4. The multi-die integration package according to claim 1, wherein the at least one IC die, the at least one bridge die, and/or the at least one sub-module are built and tested before attaching and electrically coupling to the plurality of metal contacts of the conductive metal patterns of the RDL.

5. The multi-die integration package according to claim 1, wherein the at least one IC die is on a first side of the RDL, and the at least one bridge die and the at least one sub-module are on a second side of the RDL.

6. The multi-die integration package according to claim 1, further comprising solder interconnections of the at least one IC die, the at least one bridge die, and/or the at least one sub-module to the plurality of metal contacts of the conductive metal patterns of the RDL at high stress connection locations thereof.

7. The multi-die integration package according to claim 1, wherein the plurality of metal contacts of the conductive metal patterns of the RDL are adapted to accommodate connections to the at least one IC die, the at least one bridge die and the at least one sub-module having different connection contact pitches.

8. The multi-die integration package according to claim 7, further comprising C4 connections coupled to connection contacts of the at least one bridge die and the at least one sub-module.

9. The multi-die integration package according to claim 8, wherein the multi-die structure is a plurality of multi-die structures fabricated together and then separated into individual multi-die structures.

10. The multi-die integration package according to claim 9, wherein the C4 connections of the at least one bridge die and the at the least one sub-module of each separated multi-die structure are coupled to an associated substrate.

11. The multi-die integration package according to claim 1, wherein the at least one IC die, the at least one bridge die and/or the at least one sub-module are tested before being attached and electrically coupled to the plurality of metal contacts of the conductive metal patterns of the RDL.

12. A method for fabricating a multi-die structure, comprising:
creating a first redistributed layer (RDL) on a first carrier, the first RDL comprising conductive metal patterns with a plurality of metal contacts thereon;
attaching and electrically coupling at least one bridge die to the plurality of metal contacts of the conductive metal patterns of the first RDL;
attaching and electrically coupling at least one sub-module to the plurality of metal contacts of the conductive metal patterns of the first RDL;
encasing the at least one bridge die and the at least one sub-module with a first mold material;
removing the first carrier from the first RDL and the first mold material encasing the at least one bridge die and the at least one sub-module;
attaching a second carrier to an opposite side of the at least one bridge die and the at least one sub-module;
attaching and electrically coupling at least one integrated circuit (IC) die to the plurality of metal contacts of the conductive metal patterns of the first RDL on an opposite side thereof;
encasing the at least one IC die and the opposite side of the first RDL with a second mold material;
removing the second carrier from the at least one IC die;
back grinding the at least one bridge die and the at least one sub-module to expose electrical circuit connections thereof; and
patterning and attaching contacts to the exposed electrical circuit connections.

13. The method according to claim 12, further comprising soldering interconnections of the at least one IC die, the at least one bridge die, and/or the at least one sub-module to the contacts of the conductive metal patterns of the RDL at high stress connection locations thereof.

14. The method according to claim 12, further comprising:
creating a second RDL on the first carrier, the second RDL comprising conductive metal patterns with a plurality of metal contacts thereon, the plurality of metal contacts of the first and second RDLs located on different areas of the first carrier;
attaching and electrically coupling at least one bridge die to the plurality of metal contacts of the conductive metal patterns of the second RDL;
attaching and electrically coupling at least one sub-module to the plurality of metal contacts of the conductive metal patterns of the second RDL;
encasing the at least one bridge die and the at least one sub-module of the second RDL with the first mold material;
removing the first carrier from the first and second RDLs and the first mold material encasing the at least one bridge die and the at least one sub-module of each of the first and second RDLs;
attaching the second carrier to an opposite side of the at least one bridge die and the at least one sub-module of the second RDL;
attaching and electrically coupling at least one IC die to the plurality of metal contacts of the conductive metal patterns of the second RDL;
encasing the at least one IC die and the opposite side of the second RDL with the second mold material; and
removing the second carrier from the at least one IC die of the second RDL.

15. The method according to claim 14, further comprising soldering interconnections of the at least one IC die, the at least one bridge die, and/or the at least one sub-module to the contacts of the conductive metal patterns at high stress connection locations thereof for each of the first and second RDLs.

16. The method according to claim 14, further comprising separating each of the plurality of multi-die structures.

17. An elevated fan-out bridge structure, comprising:
a minimal redistributed layer (RDL) including conductive metal patterns with a plurality of metal contacts thereon;
at least one bridge die attached and electrically coupled to the plurality of metal contacts of the conductive metal patterns of the RDL; and
at least one sub-module attached and electrically coupled to the plurality of metal contacts of the conductive metal patterns of the RDL.

18. The elevated fan-out bridge structure according to claim 17, wherein the plurality of metal contacts of the conductive metal patterns of the RDL are adapted for attaching and electrically coupling to at least one integrated circuit (IC) die.

19. The elevated fan-out bridge structure according to claim 17, wherein the plurality of metal contacts of the conductive metal patterns of the RDL are adapted for attaching and electrically coupling to at least one chiplet.

20. The elevated fan-out bridge structure according to claim 17, wherein the plurality of metal contacts of the conductive metal patterns of the RDL are adapted for attaching and electrically coupling to at least one integrated circuit (IC) die and/or at least one chiplet.
